(19) United States
(12) Patent Application Publication
(10) Pub. No.: US 2006/0157732 A1
(43) Pub. Date: Jul. 20, 2006

(54) Fabrication of MOS-gated strained-Si and SiGe buried channel field effect transistors

(75) Inventors: Hans Von Kaenel, Zurich (CH); Kristel Fobelets, London (GB); Thomas Hackbarth, Blaustein (DE)

Correspondence Address: MOETTELI & ASSOCIATES SARL, ST. LEONHARDSTRASSE 4, ST. GALLEN, CH-9000, CH

(73) Assignee: EpiSpeed SA, Zurich (CH)

(21) Appl. No.: 11/269,870

(22) Filed: Nov. 8, 2005

Related U.S. Application Data
(60) Provisional application No. 60/625,952, filed on Nov. 9, 2004.

(51) Int. Cl. H01L 31/109

(52) U.S. Cl. 257/190

(57) ABSTRACT

A method of fabricating semiconductor heterostructures including the steps of: (a) positioning a silicon wafer in a suitable environment and (b) processing the silicon substrate by applying several processing steps. A first optional processing step includes growing a graded buffer layer on a silicon substrate by low-energy plasma-enhanced chemical vapor deposition (LEPECVD). A second processing step includes growing a constant composition buffer layer by LEPECVD. A third processing step includes subjecting the surface of the strain-relaxed buffer layer to a deposition process for a period of time and under prescribed conditions, in order to grow at least one additional layer. Subsequently, devices may be processed from the grown layer stack by using a prescribed sequence of steps including non-standard CMOS processes.

### BACKGROUND OF THE INVENTION

The invention relates to the field of strained semiconductor structures on top of a strain-relaxed buffer layer, which can be applied in particular to the fabrication of integrated circuits comprising buried-channel and surface-channel strained-Si field effect transistors with a metal-oxide gate.

The beneficial role of tensile strain for enhancing the electronic properties of Si was recognized in the mid eighties by Abstreiter et al. (see Abstreiter et al., Phys. Rev. Lett. 54, 2441 (1985)), the content of which is incorporated herein by reference hereto.

Nearly 20 years of intense research on strained-Si have followed this initial discovery (see for example Schäffler, Semicond. Sci. Technol. 12, 1515 (1997), the content of which is incorporated herein by reference hereto). The most common way to impose tensile strain is by epitaxial growth. A relaxed buffer layer or virtual substrate (VS) with lattice parameter larger than that of Si is grown first, followed by the layer of strained Si. Provided that the Si layer is kept sufficiently thin, the strained-Si/VS interface remains defect-free, and the lateral lattice parameters of strained-Si and VS are equal.

In practice, an alloy layer of Si₁₋ₓGeₓ (0<x≦1) is used to form the VS, the lattice parameter of which can be chosen to lie anywhere between that of pure Si and pure Ge, since the lattice parameter of Ge exceeds that of Si by 4.2%. In order to act as VS the alloy layer must be grown beyond its critical thickness for strain relaxation, which depends on the Ge content and the method of growth. Strain relaxation proceeds by introducing misfit dislocations at the alloy layer/substrate interface. Unfortunately, these are usually accompanied by so-called threading dislocations (TDs). The TDs reach the surface of the VS and tend to pierce any electrically active layers grown on top, thereby degrading its electrical properties (see for example Ismail et al., J. Vac. Sci. Technol. B 14, 2776 (1996), the content of which is incorporated herein by reference hereto).

In U.S. Pat. No. 5,221,413, the content of which is incorporated herein by reference hereto, Brasen et al., have described a way to reduce the TD density by successively depositing alloy layers with increasing Ge content. The concept of graded SiGe alloy layers has been explained also in a seminal paper by Fitzgerald et al. (see Fitzgerald et al., Appl. Phys. Lett. 59, 811 (1991), the content of which is incorporated herein by reference thereto).

Linearly- or step-graded SiGe VS have formed the basis for most strained-Si devices processed in the past. Strained-Si devices can be divided into two broad classes: modulation doped field effect transistors (MODFETs) and metal-oxide-semiconductor field effect transistors (MOSFETs).

MODFETs are characterized by a selectively (also called modulation) doped buried channel and are considered among the fastest transistors available. Modulation doping has been applied first to the gallium arsenide-gallium aluminium arsenide system. There, facing layers of gallium arsenide and aluminium gallium arsenide force electrons into an essentially two-dimensional electron gas. The electrons which are restricted in this way are less susceptible to scattering because they are separated from their donor ions and can therefore move more quickly. Although consumer applications of such two dimensional devices, such as MODFETS have been somewhat limited, they are used in satellite television receivers where the frequency range of GaAs and the low-noise behaviour of modulation-doped devices come into play.

In Si technology, MOSFETs are on the other hand by far the most common field effect transistors in both digital and analogue circuits. The MOSFETs have a surface channel of n-type or p-type semiconductor material, and are accordingly called either NMOSFETs or PMOSFETs.

Surface channel MOSFETs have the advantage of a small gate to channel distance and hence efficient electrostatic control by the gate. They suffer, however, from interface scattering at the oxide/silicon interface. Buried channel devices are on the other hand characterized by reduced scattering at the smoother epitaxial interfaces at the expense of poorer gate control because of the larger gate to channel distance.

The present invention provides a means of combining the advantages of surface and buried channel devices. The potential benefits of buried-channel MOSFET devices have been described for example by Welser et al. in IEEE EI. Dev. Lett. 15, 100 (1994), the content of which is incorporated herein by reference thereto. Device performance was limited, however, due to transport through the low-mobility SiGe cap at high vertical field.

Under the influence of strain the mobility of Si channels is enhanced both for electrons and holes, leading to better transistor performance for n-channel as well as p-channel devices. Holes require, however, a larger amount of strain than electrons for the mobility to be significantly enhanced. This necessitates higher Ge content in the VS (see for example Fischetti et al., J. Appl. Phys. 80, 2234 (1994), and R. Oberhuber et al., Phys. Rev. B 58, 9941 (1998), the contents of which are incorporated herein by reference thereto).

With Si channels under tensile strain, MOSFET devices with enhanced mobility of both electrons and holes can be fabricated and combined in a CMOS circuit, as described for example in U.S. Pat. No. 6,649,480 to Fitzgerald et al., the content of which is incorporated herein by reference thereto.

Especially the mobility enhancement for holes seems, however, to be limited in this approach (see for example Leitz et al., J. Appl. Phys. 92, 3745 (2002), the content of which is incorporated herein by reference thereto). Here, higher enhancement factors can be achieved by using buried SiGe alloy channels (see for example Höck et al., Appl. Phys. Lett. 76, 3920 (2000), the content of which is incorporated herein by reference thereto).

It may therefore be advantageous to combine buried alloy channels for hole transport and Si surface channels for electron transport in a so-called dual-channel approach (see for example Badcock et al., Solid-State Electronics 46, 1925 (2002) and Lee et al., Appl. Phys. Lett. 83, 4202 (2003), the contents of which are incorporated herein by reference thereto).

For the actual fabrication of strained-Si devices, epitaxial growth techniques such as molecular beam epitaxy (MBE) or chemical vapor deposition (CVD) are commonly used (see for example Weitz et al. Surf. Sci. 361/362, 542 (1996), and Ismail et al., Appl. Phys. Lett. 66, 1077 (1995), respectively, the contents of which are incorporated herein by reference thereto). Both methods are characterized by low throughput, especially because of low CVD growth rates at low substrate temperatures, and the large thickness required for high-quality VS growth.

A method for epitaxy, much faster than MBE and CVD, has been presented in U.S. Pat. No. 6,454,855 by von Känel et al, the content of which is incorporated herein by reference thereto. In this patent to von Känel, the application of this so-called low-energy plasma-enhanced chemical vapor deposition (LEPECVD) technique was restricted to coherent, defect-free epitaxial interfaces (see also Rosenblad et al., J. Vac. Sci. Technol. A 16, 2785 (1998), the content of which is incorporated herein by reference thereto). The application of LEPECVD to the fabrication of relaxed graded VS has been described for example in the European Patent Application Nr. EP 1 315 199 to von Känel and in U.S. patent application No. U.S. 60/565,205, the contents of which are incorporated herein by reference thereto.

Application of LEPECVD to the fabrication of highly relaxed VS comprising a constant composition SiGe alloy layer without the use of any graded layer has been described for example by in the International Patent Application No. PCT/EP03/03136 to von Känel and by Chrastina et al., J. Cryst. Growth 281, 281 (2005), the contents of which are incorporated herein by reference thereto.

The advantages of applying LEPECVD to the fabrication of relaxed SiGe VS for MODFETs with a buried modulation doped Si channel were described for example in Appl. Phys. Lett. 76, 427 (2000) by Rosenblad et al., the content of which is incorporated herein by reference thereto.

For selectively doped buried channels the need to keep the gate to channel distance short, and the need to limit dopant diffusion and segregation during high temperature anneals, provide additional hurdles to epitaxial growth and subsequent device processing. For simpler Schottky-gated devices, excellent results have been achieved by growing the VS by LEPECVD and the active layer stack by MBE (see for example von Känel et al. in U.S. patent application No. U.S. 60/565,205, and Enciso-Aquilar et al., Electronics Letters 39, 149 (2003), the content of which is incorporated herein by reference thereto).

It is an object of the present invention to provide a method by which the higher demands of MOSFET processing can be met.

### SUMMARY OF THE INVENTION

A method of fabricating semiconductor heterostructures including the steps of: (a) positioning a silicon wafer in a suitable environment and (b) further processing the silicon substrate by applying several processing steps A first optional processing step includes growing an epitaxial graded buffer layer onto the silicon substrate by low-energy plasma-enhanced chemical vapor deposition (LEPECVD). A second processing step includes growing an epitaxial strain-relaxed constant composition buffer layer by LEPECVD. A third processing step includes subjecting the surface of the strain-relaxed buffer layer to a deposition process for a period of time and under prescribed conditions, in order to grow at least one additional layer.

The present invention provides a method for the fast growth of heterostructures comprising a strain relaxed buffer layer on Si substrates (virtual substrate, VS) with an active layer stack on top. The structures are especially suitable for the fabrication of integrated circuits based on buried-channel strained-Si field effect transistors.

It is another object of the invention to provide the necessary steps for the processing of modulation-doped field effect transistors with a metal-oxide gate (MOSMODFET).

It is another object of the invention to provide a method for performance gain of buried-channel strained-Si FETs through non-standard processing.

It is another object of the invention to provide a method for producing buried strained-Si electron and strained-SiGe hole channels for complementary CMOSFETs.

It is another object of the invention to provide a method for producing buried alloy channels combined with strained-Si surface channels for CMOSFETs.

### BRIEF DESCRIPTION OF THE DRAWINGS

FIG. 1 is a flow chart of the method of the invention.

FIG. 2 is a schematic cross-section of a buried-channel strained-Si device.

FIG. 3 is a schematic cross-section of a dual channel device with buried strained-Si and strained-SiGe channels.

FIG. 4 is a schematic cross-section of a dual channel device with a buried strained-SiGe channel and a strained-Si surface channel.

FIG. 5 shows the layer structure of a typical buried-channel strained-Si device including typical doping levels.

FIG. 6 is a flow chart of a device processing method of the invention.

FIG. 7 is a comparison of maximum intrinsic transconductances as a function of gate length for strained-Si buried-channel and bulk Si controls.

FIG. 8 is a comparison of the effective drift mobilities as a function of the vertical field for strained-Si buried-channel and bulk Si controls.

FIG. 9 is a comparison of the maximum transit frequencies at two different bias levels for strained-Si buried-channel and bulk Si controls.

### DETAILED DESCRIPTION OF THE INVENTION

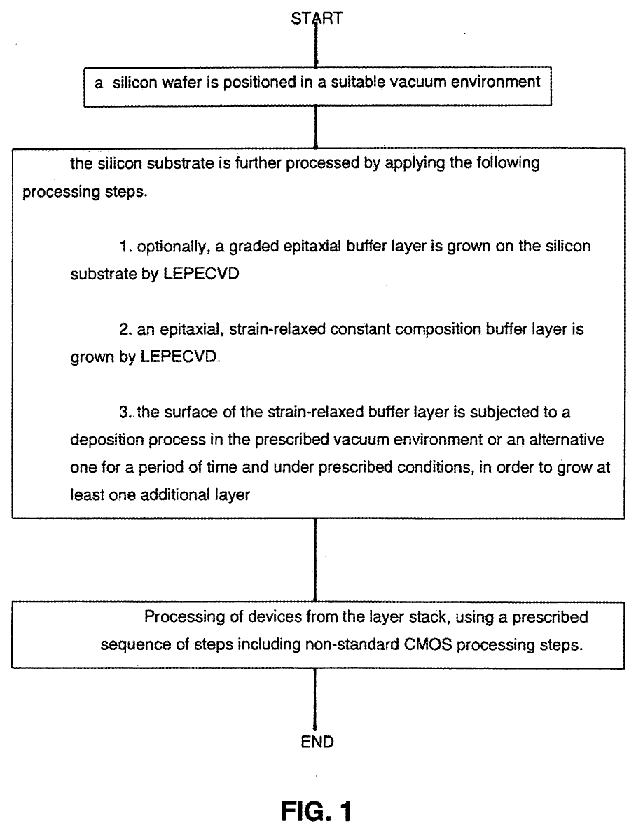

Referring now to FIG. 1, a method is provided for fabricating semiconductor heterostructures. The method includes the following three steps. In a first step 4, a silicon wafer is positioned in a suitable environment, such as a vacuum chamber equipped with a substrate heater and components suitable for epitaxial layer deposition. In a second step 6, the silicon substrate is further processed by applying several processing steps. In a first optional processing step 6a, an epitaxial graded buffer layer is grown on a the silicon substrate by low-energy plasma-enhanced chemical vapor deposition (LEPECVD). In a second processing step 6b, an epitaxial strain-relaxed constant composition buffer layer is grown by LEPECVD. In a third processing step 6c the surface of the strain-relaxed buffer layer is subjected to a deposition process for a period of time and under prescribed conditions, in order to grow at least one additional layer. In a third step 8, device processing is carried out using a prescribed sequence of processing steps including non-standard CMOS processes.

(1) Buried Si Channel Device for N-Type MOSMODFETs

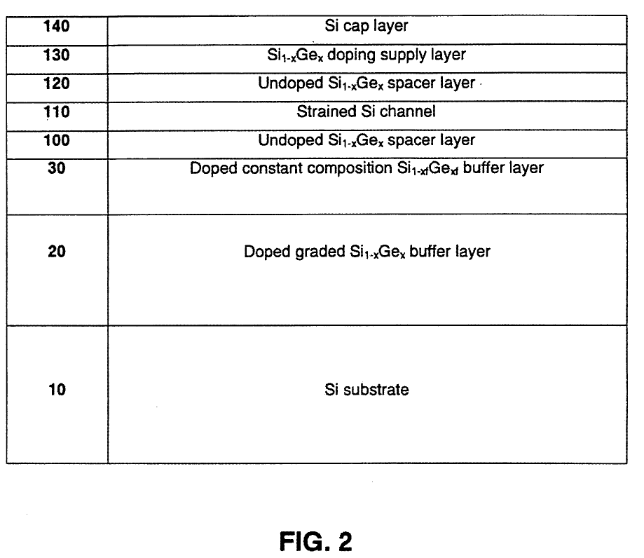

Referring now to FIG. 2, a schematic cross-section of the layer structure according to the invention is shown. In a preferred embodiment of the invention, the entire epitaxial layer structure is grown by low-energy plasma-enhanced chemical vapor deposition (LEPECVD) onto a silicon substrate 10. An epitaxial graded Si₁₋ₓGeₓ buffer layer 20 with a grading rate preferably below 10%/μm and a final Ge content x_{f} below 0.4 is grown first. After the graded layer 20 a strain-relaxed buffer layer 30 with a constant composition x_{f} is grown, preferably to a thickness of about 1 μm. Layers 20 and 30 are grown by using a high-density plasma, whereby a growth rate of several nm/s can be achieved.

In a first embodiment of the invention, preferably for Ge contents below x=0.3, the substrate temperature is kept constant during growth of layers 20 and 30. The substrate temperature is chosen such as to guarantee nearly complete relaxation of the buffer layer. For temperatures above 700° C. this has been shown to be the case.

In another embodiment of the invention, the substrate temperature is kept constant only during part of the growth of layer 20 up to approximately x=0.3, whereupon it is lowered in proportion to the Ge content. This has the advantage of lowering the surface roughness and threading dislocation (TD) density. For example for x_{f}=0.4 a final temperature of 540° C. was found to result in a TD density below 2×10⁵ cm⁻².

In another embodiment of the invention, the graded part 20 of the VS is omitted. In this case strain-relaxed layer 30 is grown directly on the silicon substrate preferably to a minimum thickness of 100 nm in the temperature range between 500° C. and 600° C. by using a high-density plasma, whereby a growth rate of several nm/s can be achieved. Layer 30 may be subjected to post-growth annealing at a temperature below 1000° C. for a period of time of about 5 min in order to increase the degree of strain relaxation.

In a preferred embodiment of the invention, the buffer layers 20 and 30 are doped during growth. For n-channel devices, p-type doping must be used, for example by boron or gallium impurities, preferably introduced at a density of about 5×10¹⁷ cm⁻³. In this embodiment, a thin undoped layer 100 is subsequently grown at a lower rate of preferably less than 0.5 nm/s by using a plasma of lower density. The substrate 10 on the other hand is high resistive p-doped.

In another embodiment, only the substrate 10 is p-doped, while the buffer layers 20 and 30 are not intentionally doped. In this case, layer 100 is optional.

In a preferred embodiment of the invention, the Ge content x of layers 100, 120, and 130 is chosen to be slightly higher than that of layer 30 in order to provide some compensation of the tensile strain imposed by the channel 110 and the Si cap layer 140.

The strained-Si channel 110 is grown at a low rate for example of 0.3 nm/s by using a low-density plasma and reduced reactive gas flow, and at a substrate temperature preferably above 500° C. Similar parameters may be used for the rest of the active layer stack 120-140. The thickness of the Si channel is chosen in accordance with the final Ge content x_{f}. For x_{f}=0.3 a thickness of 8 nm has been found to be adequate. During channel growth, a surplus of hydrogen may be added to the reactive gas flow in order to minimize the effect of Ge segregation.

The undoped alloy spacer layer 120 is grown to a thickness preferably of 4-5 nm. The doping supply layer 130 should be very thin and highly doped. A thickness of 3 nm and a doping level of at least 3×10¹⁸ cm⁻³ have been shown to yield good results.

In a preferred embodiment of the invention, doping at a level above 3×10¹⁸ cm⁻³ can be achieved by LEPECVD by lowering the substrate temperature to below 500° C., preferably to about 400° C. The plasma density is preferably kept lower by about a factor of ten with respect to that employed during growth of layers 20 and 30. A hydrogen flow of at least 5 sccm (standard cubic centimeters per minute) is added to the reactive gas mixture. This has been shown to be effective in suppressing dopant segregation to the surface.

Doping can be achieved for example by a flow of phosphine, preferably diluted with an inert gas.

The layer stack is completed by an undoped strained-Si cap 140 of a preferable thickness of not less than 2 nm and not more than 5 nm, for protection of the SiGe layers.

In another embodiment of the invention the stack of layers 100-140 is grown by an alternate deposition method, such as molecular beam epitaxy (MBE) or chemical vapor deposition (CVD) in a separate deposition chamber.

(2) Buried Si-Channel on Top of SiGe-Channel Device for Complementary CMOSMODFETs

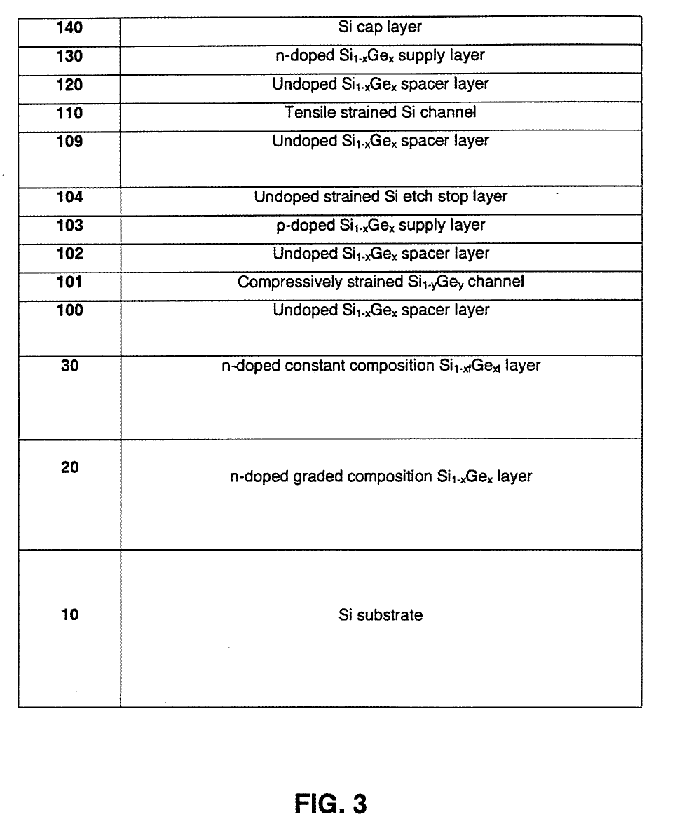

Referring now to FIG. 3, a schematic layer structure of another embodiment of the invention is shown. An epitaxial graded Si₁₋ₓGeₓ buffer layer 20 with a grading rate preferably below 10%/μm and a final Ge content x_{f} of preferably between 0.2 and 0.4 is grown by LEPECVD onto the high resistivity Si substrate 10. After the graded part, a strain-relaxed buffer layer 30 with a constant composition x_{f} is grown, preferably to a thickness of about 1 μm. Layers 20 and 30 are grown by using a high-density plasma, whereby a growth rate of several nm/s can be achieved. The layers 20 and 30 are preferably n doped to a level not less than 2×10¹⁷ cm⁻³ to act as p-channel punch-through stoppers.

In another embodiment of the invention, the graded part 20 of the VS is omitted. In this case, strain-relaxed layer 30 is grown directly on the Si substrate preferably to a minimum thickness of 100 nm in the temperature range between 500° C. and 600° C. by using a high-density plasma, whereby a growth rate of several nm/s can be achieved. Layer 30 is preferably n doped to a level not less than 2×10¹⁷ cm⁻³ to act as p-channel punch-through stopper. Layer 30 may be subjected to post-growth annealing at a temperature below 1000° C. for a period of time of about 5 min in order to increase the degree of strain relaxation.

An undoped layer 100 with a Ge content of x≦x_{f} and a preferable thickness of 20 to 60 nm is subsequently grown at a lower rate of preferably less than 0.5 nm/s by using a plasma of lower density. This layer can be designed to serve both as a strain compensating and carrier-depletion absorb layer. The substrate temperature is lowered to about 450° C. during growth of layer 100.

An undoped strained-Si_{1-y}Ge_{y} layer 101 with a Ge content of at least y=x_{f}+0.2 is grown at a low rate by using a low-density plasma and reduced reactive gas flows. The thickness of layer 101 is chosen to be about 8 nm. A hydrogen flow of at least 5 sccm is added to the reactive gas mixture. This has been shown to prevent buckling of the compressively strained Si_{1-y}Ge_{y} channel 101.

An undoped spacer layer 102 with a Ge content of x≦x_{f} and a thickness of about 4-5 nm is grown at a low rate. It may again act as a strain-compensating layer. Here, additional hydrogen is preferably used to prevent Ge segregation. During growth of layer 102, the substrate temperature may again be raised to above 500° C.

A very thin, preferably 3 nm, highly p-type doped layer 103 with a Ge content of x≦x_{f} is grown at a low rate to act as a p-type carrier supply layer and a punch-through stopper for the above lying n-channel strained-Si layers. In a preferred embodiment of the invention, doping of layer 103 at a level above 3×10¹⁸ cm⁻³ can be achieved by LEPECVD by lowering the substrate temperature to below 500° C., preferably to about 400° C. The plasma density is preferably kept lower by about a factor of ten with respect to that employed during growth of layers 20 and 30. A hydrogen flow of at least 5 sccm is added to the reactive gas mixture. This has been shown to be effective in suppressing dopant segregation to the surface. Doping can be achieved for example by a flow of boron, preferably diluted with an inert gas.

It is a preferred embodiment of the invention, to introduce a strained-Si etch stop layer 104 to facilitate removal of the top 5 layers for p-MOS processing, a preferred thickness of layer 104 is 5-10 nm.

It is a preferred embodiment of the invention, to introduce an undoped layer 109 with a Ge content of x≦x_{f} and a preferable thickness of 40 to 60 nm, this layer 109 is grown at a lower rate of preferably less than 0.5 nm/s by using a plasma of lower density. This layer can be designed to serve both as a strain compensating and carrier-depletion absorption layer. It furthermore anticipates a parasitic parallel conduction in the n-type doped layers 20 and 30 via the n-type contact implantation described below. The substrate temperature is lowered to about 450° C. during growth of layer 109.

In another embodiment, the Ge content x of layer 109 is chosen to be slightly above that of layer 30, x≧x_{f}. This is preferable when the tensile strain imposed by layers 104, 110 and 140 becomes too large to be compensated by the compressively strained Si_{1-y}Ge_{y} channel 101. The resulting strain of the entire heterostructure may be tuned to near zero through proper choice of Ge content of layer 109. Furthermore, a higher Ge content of layer 109 will improve the efficacy of layer 104 as an etch stop layer because of enhanced selectivity.

The strained-Si channel 110 is grown at a low rate for example of 0.3 nm/s by using a low-density plasma and reduced reactive gas flow, and at a substrate temperature preferably above 500° C. Similar parameters may be used for the rest of the active layer stack 120-140. The thickness of layer 110 is chosen to be equal or less than 8 nm. During channel growth, a surplus of hydrogen may be added to the reactive gas flow in order to minimize the effect of Ge segregation.

The undoped alloy spacer layer 120 is grown to a thickness of preferably 4-5 nm.

The doping supply layer 130 should be very thin and highly doped. A thickness of 3 nm and a doping level of at least 3×10¹⁸ cm⁻³ have been shown to yield good results. The Ge content of layers 120 and 130 is preferably chosen to be close to x_{f}.

In a preferred embodiment of the invention, doping of layer 130 at a level above 3×10¹⁸ cm⁻³ can be achieved by LEPECVD by lowering the substrate temperature to below 500° C., preferably to about 400° C. The plasma density is preferably kept lower by about a factor of ten with respect to that employed during growth of layers 20 and 30. A hydrogen flow of at least 5 sccm is added to the reactive gas mixture. This has been shown to be effective in suppressing dopant segregation to the surface.

Doping can be achieved for example by a flow of phosphine, preferably diluted with an inert gas.

The layer stack is completed by an undoped strained Si cap 140 of not less than 2 nm and of not more than 5 nm.

In another embodiment of the invention the stack of layers 100-140 is grown by an alternate deposition method, such as molecular beam epitaxy (MBE) or chemical vapor deposition (CVD) in a separate deposition chamber.

(3) Si Surface Channel on Top of Buried SiGe-Channel Device for Complementary CMOSFETs

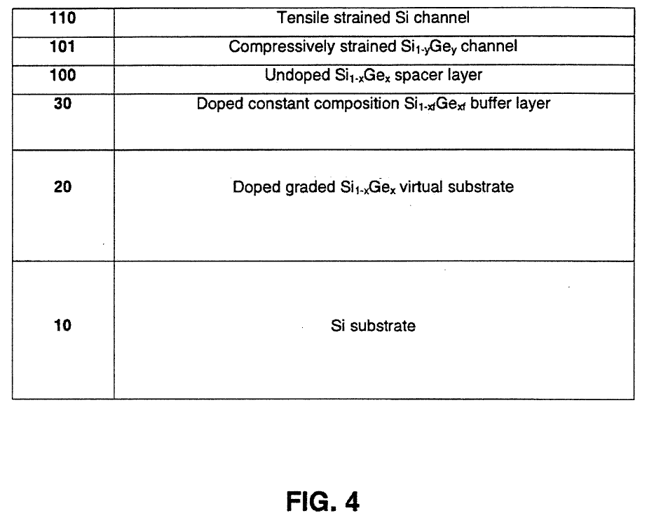

Referring now to FIG. 4, a schematic cross-section of another embodiment of the invention is shown. An epitaxial graded Si₁₋ₓGeₓ buffer layer 20 with a grading rate preferably below 10%/μm and a final Ge content x_{f} of preferably about 0.4 is grown by LEPECVD onto the undoped substrate 10. After this, the graded part a strain-relaxed buffer layer 30 with a constant composition x_{f} is grown, preferably to a thickness of about 1 μm. Layer 20 and most of layer 30 are grown by using a high-density plasma, whereby a growth rate of several nm/s can be achieved. Layers 30 and 20 are preferably n-type doped to a level around 10¹⁷ cm⁻³.

In another embodiment of the invention, the graded part 20 of the VS is omitted. In this case, strain-relaxed layer 30 is grown preferably to a minimum thickness of 100 nm in the temperature range between 500° C. and 600° C. by using a high-density plasma, whereby a growth rate of several nm/s can be achieved. Layer 30 is preferably n doped to a level around 10¹⁷ cm⁻³. Layer 30 may be subjected to post-growth annealing at a temperature below 1000° C. for a period of time of about 5 min in order to increase the degree of strain relaxation.

An undoped layer 100 with a Ge content of x≦x_{f} and a preferable thickness of 50 to 100 nm is subsequently grown at a lower rate of preferably less than 0.5 nm/s by using a plasma of lower density. This layer can be designed to serve both as carrier-depletion absorption layer and as a means to simplify the processing complexity by allowing less stringent control of ohmic contact implantation depths. The substrate temperature is lowered to about 450° C. during growth of layer 100.

The undoped strained Si_{1-y}Ge_{y} channel layer 101 with a Ge content y exceeding x_{f} by at least 0.2 is grown at a low rate by using a low-density plasma and reduced reactive gas flows. Before growth of the channel 101, the substrate temperature is lowered to approximately 450° C. The thickness of layer 101 is chosen to be below or slightly above the critical thickness for strain relaxation. A hydrogen flow of at least 5 sccm is added to the reactive gas mixture. This has been shown to prevent buckling of the compressively strained Si_{1-y}Ge_{y} channel 101. An undoped Si surface channel 110 is finally grown at a low rate for example of 0.3 nm/s by using a low-density plasma and reduced reactive gas flow, and at a substrate temperature preferably above 500° C. After initiation of Si channel growth, the hydrogen flow is preferably stopped. The preferable minimum thickness of the strained-Si channel is 5 nm.

In another embodiment of the invention the stack of layers 100-110 is grown by an alternate deposition method, such as molecular beam epitaxy (MBE) or chemical vapor deposition (CVD) in a separate deposition chamber.

(4) Device Processing and Characterization

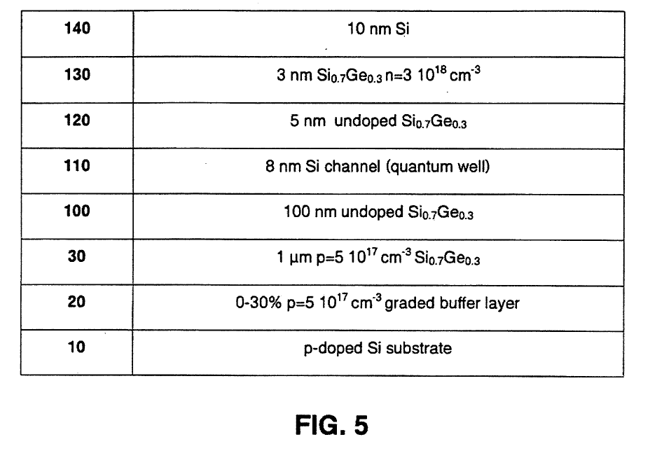

Referring now to FIG. 5, the layer structure of a buried-channel strained-Si device which has been grown and processed according to the invention is shown in more detail. The layer structure comprises the same stack as the one described more generally in FIG. 2. A key feature is the thin, highly doped supply layer 130 which provides an adequate carrier density in the channel while avoiding parallel conduction.

In the preferred embodiment of the invention, the alloy spacer layer 120 and the doping supply layer 130 were chosen to be 5 and 3 nm thin, respectively, in order to keep the distance between gate and channel small and hence to facilitate a high transconductance of the device.

Further, the protective Si cap layer should be removed as completely as possible, using a 20 s HF dip followed by a selective tetramethylammonium hydroxide ((CH3) 4NOH-TMAH) etch.

In addition to standard CMOS processes a number of non-standard CMOS processes have been employed for device fabrication.

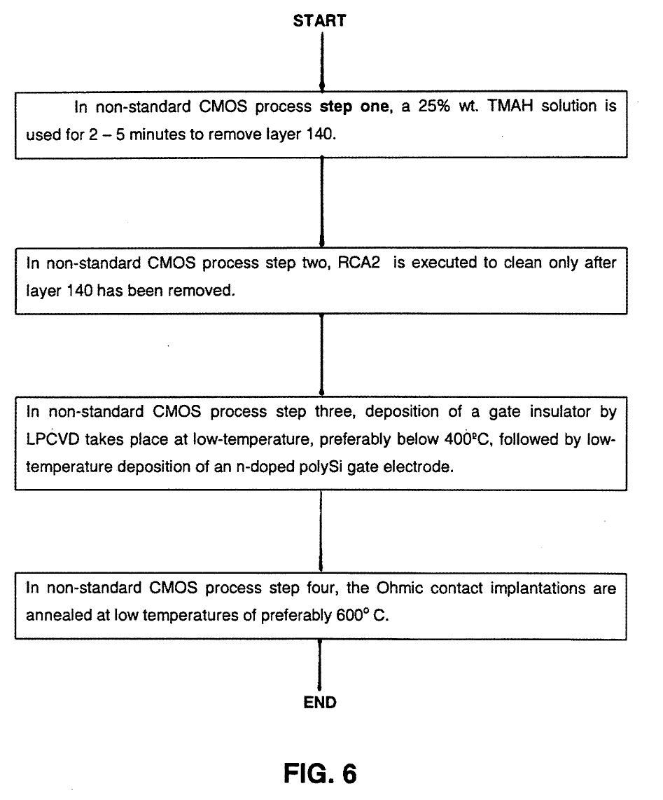

Referring now to FIG. 6, in a first non-standard CMOS process step, a 25% wt. TMAH solution is used for 2-5 minutes. The removal of layer 140 before the deposition of the gate oxide avoids a parasitic surface channel.

In a second non-standard CMOS process step, RCA2 (ULSI Technology, C. Y. Chang and S. M. Sze, Mc Graw-Hill International Editions (1996), the contents of which are incorporated herein by reference thereto) is executed to clean after layer 140 has been removed. This step avoids deterioration of the SiGe supply layer.

In a third non-standard CMOS process step, deposition of a gate insulator takes place at low-temperature, preferably below 400° C., this being an object of the invention. In the embodiment of the invention, a low-temperature LPCVD SiO₂ is deposited at 400° C. This step three avoids dopant segregation. In the embodiment of the invention, a 20 nm thick SiO₂ is deposited for low leakage current and high homogeneity. In a preferred embodiment of the invention, an in-situ doped n-type polySi gate electrode layer has to be deposited using low-temperature LPCVD to avoid the necessity for high thermal anneals.

In a fourth non-standard CMOS process step, the Ohmic contact implantations are annealed at low temperatures of preferably 600° C. In a preferred embodiment of the invention, a RTA anneal at 600° C. for 60 s is employed. This approach has been shown to give acceptable contact resistance values around 1.2 Ωmm. It is a preferred embodiment of the invention to have 1 anneal step only for all implantations in double channel devices (see FIG. 3 and FIG. 4).

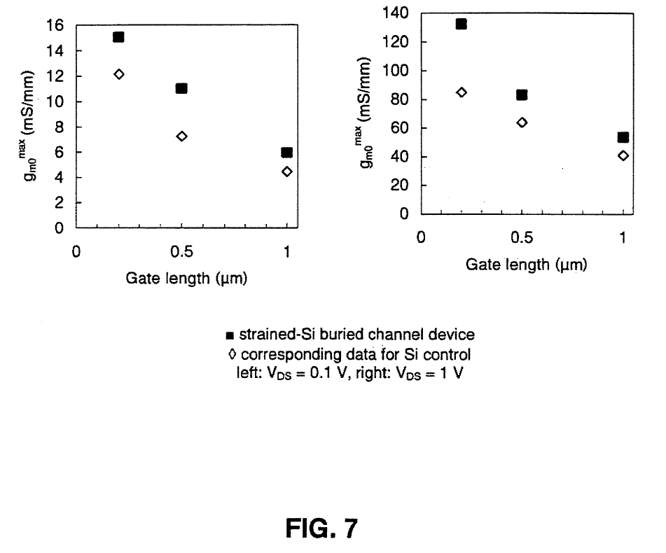

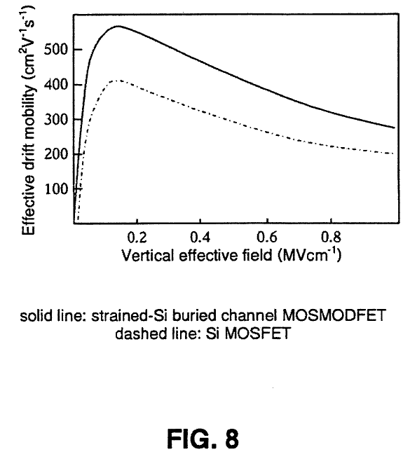

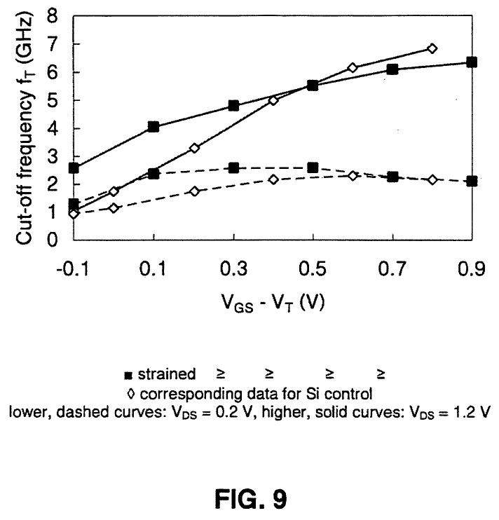

Referring now to FIG. 7, FIG. 8 and FIG. 9, the characteristics of a buried-channel strained-Si MOSMODFET which has been grown and processed according to the invention are shown in more detail.

For the buried-channel strained-Si MOSMODFET, the maximum intrinsic transconductance as a function of the gate length is compared in Erreur ! Source du renvoi introuvable. with the results of the control bulk-Si MOSFET, processed according to the process steps as defined by the invention. The intrinsic transconductance for the buried-channel strained-Si FET shows an improvement of around 50% with respect to that of the bulk-Si control.

Referring again to FIG. 8, the effective drift mobility as a function of effective vertical electric field [K. Michelakis, et al., IEEE Trans. Electron Dev. 51(8) pp 1309 (2004), the content of which is incorporated herein by reference thereto] is given for both the buried-channel strained-Si MOSMODFET and the Si MOSFET processed according to the invention. The effective drift velocity of the buried-channel strained-Si MOSMODFET is 50% higher than that of the Si MOSFET.

Referring again to FIG. 9, the cut-off frequency is compared for the buried-channel strained-Si MOSMODFET and the control Si MOSFET as a function of gate voltage overdrive. The gate length is 200 nm. The cut-off frequency for the buried-channel strained-Si MOSMODFET is larger than that of the Si MOSFET over a wide gate voltage overdrive range. In another embodiment of the invention where thinner gate oxides (3 nm) or thick high-k gate insulator are used the cut-off frequency would increase by a factor of 1.6.

In an advantage, a method is provided for fabricating buried channel field effect transistors with metal-oxide gates which combine the advantages of modulation-doped heterostructures and MOSFET processing.

In another advantage, a method for the fast growth of heterostructures is provided comprising a strain relaxed buffer layer on Si substrates (virtual substrate, VS) with an active layer stack on top. The structures are especially suitable for the fabrication of integrated circuits based on buried-channel strained-Si field effect transistors.

It is an object of the invention to provide the necessary steps for the processing of modulation-doped field effect transistors with a metal-oxide gate (MOSMODFET).

It is another object of the invention to provide a method for performance gain of buried-channel strained-Si FETs through non-standard processing.

It is another object of the invention to provide a method for producing buried strained-Si electron and strained-SiGe hole channels for complementary CMOSFETs.

It is another object of the invention to provide a method for producing buried alloy channels combined with strained-Si surface channels for CMOSFETs. Multiple variations and modifications are possible in the embodiments of the invention described here. Although certain illustrative embodiments of the invention have been shown and described here, a wide range of modifications, changes, and substitutions is contemplated in the foregoing disclosure. In some instances, some features of the present invention may be employed without a corresponding use of the other features. Accordingly, it is appropriate that the foregoing description be construed broadly and understood as being given by way of illustration and example only, the spirit and scope of the invention being limited only by the appended claims.

What is claimed is:

1. A method of fabricating semiconductor heterostructures, the method including the steps of:
(a) positioning a silicon wafer in a suitable environment so as to expose a silicon substrate for further processing;
(b) growing an epitaxial buffer layer by low-energy plasma-enhanced chemical vapor deposition (LEPECVD) on the silicon substrate; and
(c) subjecting the surface of the buffer layer to a deposition process for a period of time and under prescribed conditions, in order to grow at least one additional layer.

2. The method of claim 1, wherein, the buffer layer is strain relaxed and is formed by first growing a graded layer on the silicon substrate followed by a constant composition layer.

3. The method of claim 2, wherein the buffer layer is a doped graded Si₁₋ₓGeₓ layer, the grading rate preferably being below 10% per micron and the final Ge content x_{f} being below 0.4; and where the constant-composition layer is a Si₁₋ₓGeₓ layer with a Ge content x equal to or close to x_{f}.

4. The method of claim 1, wherein the epitaxial buffer layer is a strain-relaxed constant-composition Si_{1-xf}Ge_{xf} layer grown directly on the silicon substrate.

5. The method of claim 3, wherein the substrate temperature is kept constant during growth of the doped graded layer and the doped constant-composition buffer layer.

6. The method of claim 5, wherein the substrate temperature is maintained above 700° C.

7. The method of claim 5, wherein the substrate temperature is kept constant only during part of the growth of layer up to approximately x=0.3, whereupon it is lowered in proportion to the Ge content, thereby lowering the surface roughness and threading dislocation (TD) density.

8. The method of claim 7, wherein the strain-relaxed buffer layer is grown at a temperature between 500 and 600° C.

9. The method of claim 4, wherein the strain-relaxed buffer layer is grown at a temperature between 500 and 600° C.

10. The method of claim 4, wherein the strain-relaxed buffer layer is annealed after growth.

11. The method of claim 10, wherein the annealing temperature does not exceed 1000° C.

12. The method of claim 3, wherein the final Ge content x_{f} is maintained at x≦0.3.

13. The method of claim 1, wherein the constant composition buffer layer, having a constant composition x_{f}, is grown to a thickness of minimum 100 nm.

14. The method of claim 1, wherein the buffer layers are doped with impurities during growth, preferably to about 2×10¹⁷ to 5×10¹⁷ cm⁻³.

15. The method of claim 14, wherein further the silicon substrate is high resistive p-doped.

16. The method of claim 1, wherein the additional layers are grown into active layer stacks comprising n- and p-channels.

17. A method of fabricating strained-channel semiconductor devices, the method including the steps of:
(a) positioning a silicon wafer in a suitable environment and
(b) processing the silicon substrate by applying steps selected from a group of steps consisting of:
(i) growing a graded buffer layer on the silicon substrate by low-energy plasma-enhanced chemical vapor deposition (LEPECVD); and
(ii) further growing a constant composition buffer layer by LEPECVD; and
(iii) subjecting the surface of the strain-relaxed buffer layer to a deposition process for a period of time and under prescribed conditions, in order to grow additional layers comprising at least one strained channel and at least one supply layer doped with impurities, preferably introduced at a density of at least 3×10¹⁸ cm⁻³.

18. The method of claim 17, wherein the deposition process in (iii) is LEPECVD.

19. A method of fabricating strained-channel semiconductor device, the method including the steps of:
(a) positioning a silicon wafer in a suitable environment;
(b) growing a constant-composition buffer layer on the silicon substrate by LEPECVD; and
(c) subjecting the surface of the strain-relaxed buffer layer to a deposition process for a period of time and under prescribed conditions, in order to grow additional layers comprising at least one strained channel and at least one supply layer doped with impurities, preferably introduced at a density of at least 3×10¹⁸ cm⁻³.

20. The method of claim 19, wherein the deposition process in (c) is LEPECVD.

21. The method of claim 18, wherein the layers grown subsequently to the strain-relaxed buffer layer are grown at a lower rate of preferably less than 0.5 nm/s by using a plasma of lower density.

22. The method of claim 20, wherein the layers grown subsequently to the strain-relaxed buffer layer are grown at a lower rate of preferably less than 0.5 nm/s by using a plasma of lower density.

23. The method of claim 1, wherein the silicon substrate is undoped, whereas the buffer layers are n-doped, and all subsequent layers are not intentionally doped.

24. The method of claim 1, wherein doping at a level above 3×10¹⁸ cm⁻³ is achieved by LEPECVD by lowering the substrate temperature to below 500° C., preferably to about 400° C.

25. The method of claim 17, wherein doping at a level above 3×10¹⁸ cm⁻³ is achieved by LEPECVD by lowering the substrate temperature to below 500° C., preferably to about 400° C.

26. The method of claim 19, wherein doping at a level above 3×10¹⁸ cm⁻³ is achieved by LEPECVD by lowering the substrate temperature to below 500° C., preferably to about 400° C.

27. The method of claim 18, wherein the plasma density is preferably kept lower than that employed during growth of layers by approximately a factor of ten.

28. The method of claim 20, wherein the plasma density is preferably kept lower than that employed during growth of layers by approximately a factor of ten.

29. The method of claim 18, wherein a hydrogen flow of at least 5 sccm is added to the reactive gas mixture
(a) during growth of layers thereby effectively suppressing dopant segregation to the surface; and
(b) further during growth of the compressively strained channels thereby effectively suppressing surface buckling.

30. The method of claim 18, wherein doping is achieved for example by a flow of phosphine or diborane, preferably diluted with an inert gas.

31. The method of claim 17, wherein the layer stack is completed by an undoped strained-Si cap of a preferable thickness of not less than 2 nm and not more than 5 nm, for protection of the SiGe layers.

32. A method of fabricating a buried Si-channel on top of SiGe-channel device for complementary CMOSMODFETs, the method applying LEPECVD to build up additional layers.

33. A method of fabricating a Si surface channel on top of buried SiGe-channel device for complementary CMOSFETs, the method applying LEPECVD to build up additional layers.

34. A method of fabricating a Si buried channel for n-type MOSMODFETs the method applying LEPECVD to build up additional layers.

35. A method of fabricating a Si buried channel for n-type MOSMODFETs, the method including the following steps:
(a) removing the protective Si cap layer completely, using a 20 s HF dip followed by a selective tetramethylammonium hydroxide ((CH3) 4NOH-TMAH) etch;
(b) applying RCA2 cleaning only after the 10 nm Si layer has been removed, thereby avoiding deterioration of the SiGe supply layer;
(c) further applying low-temperature deposition, preferably below 400° C., of a gate insulator;
(d) optionally, depositing an in-situ doped n-type polySi gate electrode layer using low-temperature LPCVD to avoid the necessity for high thermal anneals; and
(e) implanting Ohmic contacts, and annealing Ohmic contact implantations at low temperatures of preferably 600° C.

36. The method of claim 35, wherein, in step (a), a 25% wt. TMAH solution is used for 2-5 minutes.

37. The method of claim 35, wherein, in step (c), a low-temperature LPCVD SiO₂ is deposited at 400° C. in order to avoid dopant segregation.

38. The method of claim 35, wherein, in step (f), preferably, a RTA anneal at 600° C. for 60 s is employed in order to yield acceptable contact resistance values around 1.2 Ωmm.

39. The method of claim 35, wherein, preferably, only one anneal step is applied for all implantations in double channel devices.
